(19) United States
(12) Patent Application Publication
(10) Pub. No.: US 2007/0037376 A1
(43) Pub. Date: Feb. 15, 2007

(54) Method and apparatus for fine pitch solder joint

(75) Inventor: Dan Okamoto, Oita (JP)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 11/201,716

(22) Filed: Aug. 11, 2005

(51) Int. Cl. H01L 21/44; H01L 21/00

(52) U.S. Cl. 438/612; 438/106; 438/107; 438/613

(57) ABSTRACT

According to one embodiment of the invention, a method of assembling a package has been provided that includes coupling a plurality of solder balls to a first surface of a substrate. At least one of the plurality of solder balls is in communication with a trace that extends from the first surface of the substrate to a second surface of the substrate. A removable laminate is disposed over the plurality of solder balls. A die is coupled to the second surface of the substrate. Communication between the die and the at least one of the plurality of solder balls is established through the trace by wire bonding the die to the trace. A mold compound is disposed around the die. The removable laminate may then be removed to expose the plurality of solder balls.

### TECHNICAL FIELD OF THE INVENTION

This invention relates generally to the field of semiconductor devices and, more particularly, to a method and apparatus for fine pitch solder joint.

### BACKGROUND OF THE INVENTION

Certain types of semiconductor packages include a die mounted on a substrate and embedded within a mold compound. The die is in communication with one or more solder joints or balls. Such semiconductor packages may be connected to a printed circuit board of an electronic device using the one or more solder joints or balls.

In the fabrication of such semiconductor packages, difficulties can be encountered due, in part, to effects of package warpage. Package warpage is caused, among other reasons, by a difference in a coefficient of linear expansion between the mold compound and the substrate utilized in the package. When such package warpage occurs, the solder joints or balls in the package may be disturbed, negatively impacting the performance of the solder joints or balls. And, in certain circumstances, such disturbances may render the solder joints or balls unsuitable for operation.

A demand exist in the semiconductor fabrication industry for smaller-sized semiconductor packages. However, when fine pitch solder balls are utilized in thin packages, the effects of warpage on the solder balls are exacerbated.

### SUMMARY OF THE INVENTION

According to one embodiment of the invention, a method of assembling a package has been provided that includes coupling a plurality of solder balls to a first surface of a substrate. At least one of the plurality of solder balls is in communication with a trace that extends from the first surface of the substrate to a second surface of the substrate. A removable laminate is disposed over the plurality of solder balls. A die is coupled to the second surface of the substrate. Communication between the die and the at least one of the plurality of solder balls is established through the trace by wire bonding the die to the trace. A mold compound is disposed around the die. The removable laminate may then be removed to expose the plurality of solder balls.

Certain embodiments of the invention may provide numerous technical advantages. For example, a technical advantage of one embodiment may include the capability to protect solder joints during assembly of a package. Other technical advantages of other embodiments may include the capability to protect fine pitch solder joints from warpage of a package during assembly of the package.

Although specific advantages have been enumerated above, various embodiments may include all, some, or none of the enumerated advantages. Additionally, other technical advantages may become readily apparent to one of ordinary skill in the art after review of the following figures and description.

### BRIEF DESCRIPTION OF THE DRAWINGS

For a more complete understanding of example embodiments of the present invention and its advantages, reference is now made to the following description, taken in conjunction with the accompanying drawings, in which:

FIG. 1A shows a side cross-sectional view of a package portion with a substrate, according to an embodiment of the invention;

FIG. 1B shows a side cross-sectional view of an addition of solder joints or balls to the package portion of FIG. 1A, according to an embodiment of the invention;

FIG. 1C shows a side cross-sectional view of an addition of a laminate to the package portion of FIG. 1B, according to an embodiment of the invention;

FIG. 1D shows a side cross-sectional view of an addition of a die and a wire bond to the package portion of FIG. 1C, according to an embodiment of the invention;

FIG. 1E shows a side cross-sectional view of an addition of mold compound to the package portion of FIG. 1D, according to an embodiment of the invention;

FIG. 1F shows a side-cross sectional view of a package, according to an embodiment of the invention; and

FIG. 2 depicts a process for preparing a package, according to an embodiment of the invention.

### DETAILED DESCRIPTION OF EXAMPLE EMBODIMENTS OF THE INVENTION

It should be understood at the outset that although example embodiments of the present invention are illustrated below, the present invention may be implemented using any number of techniques, whether currently known or in existence. The present invention should in no way be limited to the example embodiments, drawings, and techniques illustrated below, including the embodiments and implementation illustrated and described herein. Additionally, the drawings are not necessarily drawn to scale.

There is a demand in the semiconductor fabrication industry for smaller-sized semiconductor packages. However, when fine pitch solder balls are utilized in thin packages, the effects of warpage on the solder balls are exacerbated. Accordingly, teachings of some embodiments of the invention recognize a system and method for protecting solder balls during an assembly of a package.

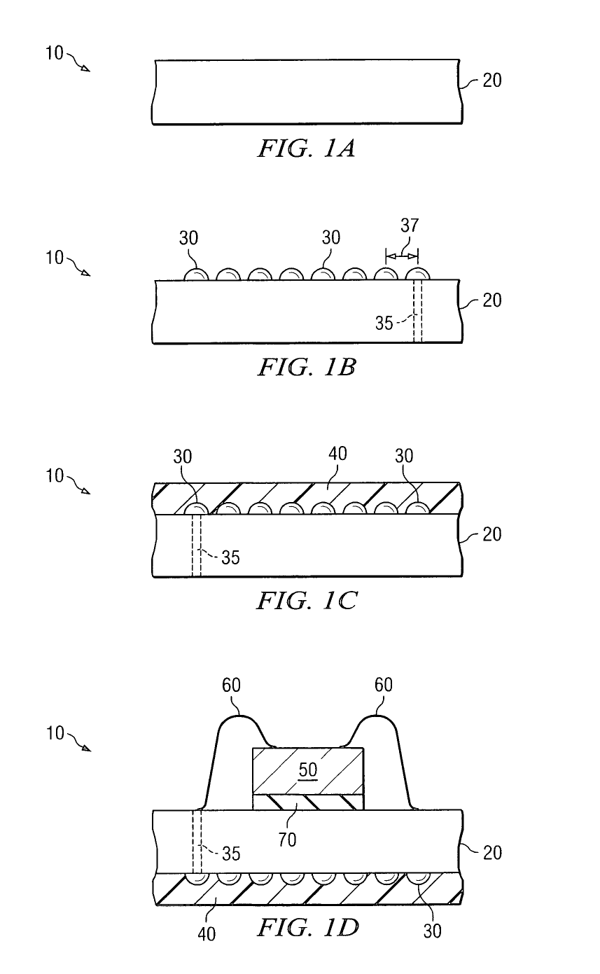

FIGS. 1A-1F depict various stages in an assembly process of a package portion 10 to produce a covered package 95 as seen in FIG. 1E and a package 90 as seen in FIG. 1F, according to an embodiment of the invention. As described in further details below, in particular embodiments the package 90 may be installed on a printed circuit board (not explicitly shown) and the covered package 95 may be utilized for protective shipment of the package 90.

FIG. 1A shows a side-cross sectional view of a package portion 10 with a substrate 20, according to an embodiment of the invention. The substrate 20 in particular embodiments may be a foundation for the package portion 10 used to create the package 90 of FIG. 1F. The substrate 20 may be made of a variety of materials including, but not limited, glass epoxy materials, polyimide-based materials, other suitable materials, and combinations of the preceding.

FIG. 1B shows a side-cross sectional view of an addition of solder joints or balls 30 to the package portion 10 of FIG. 1A, according to an embodiment of the invention. The solder joints or balls 30 in particular embodiments may be utilized to couple package 90 (seen in FIG. 1F) to appropriate portions of a printed circuit board to establish communications between components within the package (e.g., the die 50 seen in FIG 1F). The solder balls 30 (e.g., ball-grid array balls) may be coupled to the substrate 20 using a variety of techniques, including, but not limited to, screen print and reflow. Although screen print and reflow has been described in this embodiment, other embodiments may attach solder balls 30 to the substrate 20 using other techniques. In the coupling of solder balls 30 to the substrate 20, traces 35 may be established through the substrate 20. Although only one trace 35 is shown (in ghosted view) extending through substrate 20 in the package portion 10 of FIG. 1B, more than one trace 35 may be present in other embodiments. In particular embodiments, the center-to-center spacing of the solder joints or balls 30 may be less than 50 mils, less than 25 mils, less than 15 mils, or less. For purposes herein, a “mil” is approximately 0.001 inches. Such small spacing between the solder joints or balls 30 is typically referred to as “fine pitch”.

FIG. 1C shows a side-cross sectional view of an addition of a laminate 40 to the package portion 10 of FIG. 1B, according to an embodiment of the invention. The laminate 40 in this embodiment is a removable film placed over the solder joints or balls 30. In particular embodiments, the laminate 40 may be operable to protect the solder balls 30 from effects of package warpage and to withstand operating temperatures. “Withstanding operating temperatures” may generally refer to an ability of the laminate 40 to protect the solder balls 30 from warpage during an operation in which the laminate 40 will be exposed to thermal energy. For example, the laminate 40 may protect the solder balls 30 during an injection molding process, described in further details below.

In particular embodiments, suitable materials for the laminate 40 may include a variety of films, which can incorporate materials similar or different than the substrate 20. For example, the laminate 40 may incorporate glass epoxies, polyimide-based adhesives or tapes, and combinations of the proceeding. Other embodiments may utilize other suitable materials for the laminate 40 to protect the solder balls 30 from effects of package warpage and to withstand operating temperatures.

FIG. 1D shows a side-cross sectional view of an addition of a die 50 and a wire bond 60 to the package portion 10 of FIG. 1C, according to an embodiment of the invention. The die 50 may be attached to the substrate 20, utilizing a variety of die bonds 70, including epoxy, polyimide, other adhesive chemistries, mixture of such chemistries, solder, a gold-silicon Eutectic layer, or other suitable material for bonding the die 50 to the substrate 20. In various embodiments, the die bonds 70 may establish both a mechanical and thermal connection between the die 50 and the substrate 20.

The die 50 may provide the foundation for a variety of semiconductor features, including but not limited to, analog and/or digital circuits such as digital to analog converters, computer processor units, amplifiers, digital signal processors, controllers, transistors, or other semiconductor features or other integrated circuits. The die 50 may comprise a variety of materials including silicon, gallium arsenide, or other suitable substrate materials. Although a die 50 has been shown in this embodiment, a variety of other passive and active components may additionally be utilized in lieu of or in addition to the die 50 in other embodiments of the invention.

After the die 50 has been coupled to the substrate 20, the package portion 10 may be forwarded to a wire bonding process to establish communication between the die 50 and any other suitable component. For example, in the embodiment of FIG. 1D, a wire bond 60 may be coupled to a portion of the die 50 and a trace 35 on a surface 25 of the substrate 20 to establish communication between one of the solder balls 30 and the die 50. Such a configuration, for example, may be utilized to communicate electrical current or power from the solder ball 30 through the trace 35 and wire bonds 60 to the die 50. Current, communicated away from the die 50, may take an opposite path. Although such an example communication is illustrated above, other communications may be established between the die 50 and other components as will be recognized by one of ordinary skill in the art.

FIG. 1E shows a side cross-sectional view of an addition of mold compound 80 to the package portion 10 of FIG. 1D, according to an embodiment of the invention. After the die 50, the wire bonds 60, and any other suitable components have been incorporated into the package portion 10 shown in FIG. 1D, the package portion 10 may be forwarded to a molding process to place a mold compound 80 around the die 50, wire bonds 60, and die bond 70. One suitable molding process is an injection molding process. However, other suitable molding process may be utilized to place mold compound 50 around the die 50, wire bonds 60, and die bond 70.

Any suitable mold compound 80 operable to encapsulate the die 50, wire bonds 60, and die bond 70 may be utilized. Examples include, but are not limited to, a “green” mold compound that does not contain bromine (Br) or antimony (Sb). Although such mold compounds have been described, other suitable mold compounds operable to encapsulate the die 50, wire bonds 60, and die bond 70 in place may be utilized.

After suitable curing of the mold compound 80, the package portion 10 becomes a covered package 95 as shown in FIG. 1E. During the molding process (including curing), the laminate 40 in particular embodiments serves to protect the solder balls 30 from effects of warpage that may be imparted on the mold compound 80 and/or the substrate 20. In particular embodiments, the laminate 40 may additionally be retained for shipment of the covered package 95 to a particular location and then removed at the particular location. In such embodiments, the laminate 40 may serve to protect the solder balls 30 during shipment.

FIG. 1F shows a side-cross sectional view of a package 90, according to an embodiment of the invention. Upon removal of the laminate 40 from covered package 95, the solder balls 30 are, once again, exposed. In particular embodiments, the solder balls 30 retain a clear surface due to protection by the laminate 40. Additionally, in particular embodiments as referenced above, the laminate 40 helps protect the solder balls 30 from effects of warpage that may have been imparted to the package 90. After removal of the laminate 40, the package 90 may be mounted on a printed circuit board, for example, using the solder balls 30. As one example, intended only for illustrative purposes, the package 90 may be soldered to a printed circuit board using solder balls 30.

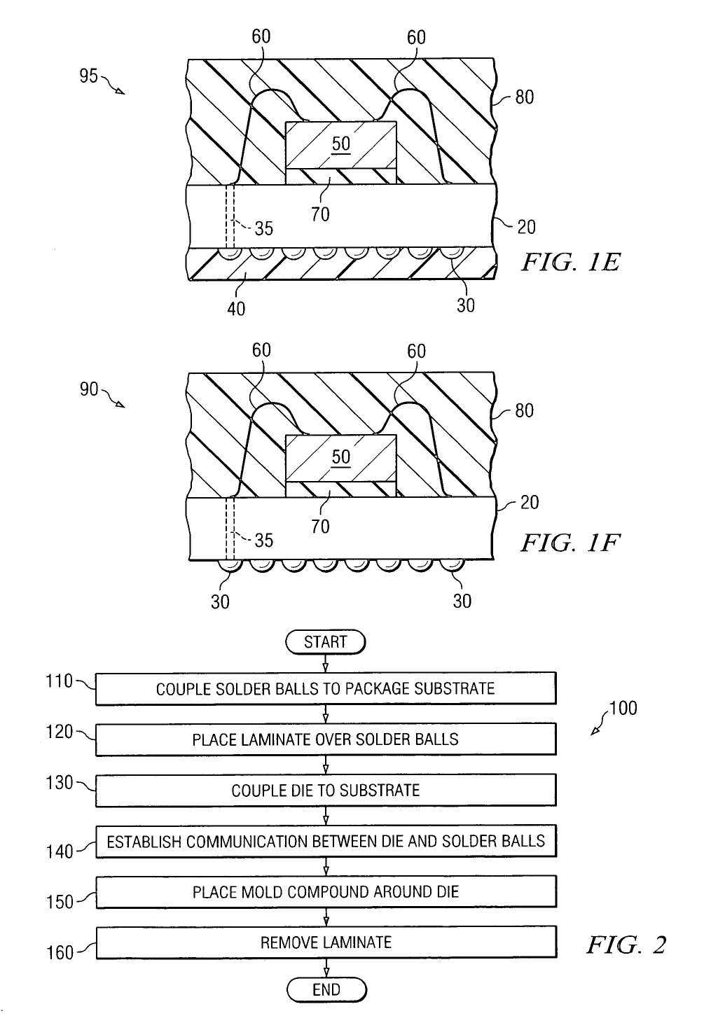

FIG. 2 depicts a process 100 for preparing a package 90, according to an embodiment of the invention. In describing the process 100 of FIG. 7, reference will also be made to FIGS. 1A through 1F. The process 100 generally begins by coupling solder balls 30 to the substrate 20 at step 110, for example, as seen in FIG. 1B. As described above, a variety of techniques may be utilized in coupling the solder balls 30 to the substrate 20 including, but not limited to, screen print and reflow.

After the solder balls 30 are coupled to the substrate 20, a laminate 40 may be placed over the solder balls at step 120. In particular embodiments, the laminate 40 may provide a protective covering for the soldering balls 30. This protective covering may minimize warping effects encountered by the package.

The process 100 may then proceed by coupling a die 50 to the substrate 20 at step 130. As referenced above, a variety of materials may be utilized, including, but not limited to, epoxy, polyimide, other adhesive chemistries, mixture of such chemistries, solder, a gold-silicon Eutectic layer, or other suitable material for bonding the die 50 to the substrate 20.

After the die 50 is in place, the process 100 may proceed to an establishment of communication between the die 50 and the solder balls 30 at step 140. As illustrated in FIG. 1D, wire bonds 60 may be coupled to both the die 50 and a trace 35 that extends through the substrate 20 to the solder balls 30.

After the communications are established between the die 50 and other components (e.g., the solder balls 30), the process 100 may proceed to a placement of mold compound 80 around the die 50 at step 150. If wire bonds 60 are used in the process, the mold compound 80 may additionally surround the wire bonds 60.

After an appropriate curing of the mold compound 80, the package portion 10 may be transformed into a covered package 95, for example, as seen in FIG. 1E. In some embodiments, the covered package 95 may be transported to a particular location with the laminate 40 protecting the solder balls during shipment or transport.

From the state of the covered package 95, the laminate 40 may be removed at step 160 to form the package 90. As briefly referenced above, the package 90 may be installed on a printed circuit board.

Although the description with reference to FIGS. 1A-1F and 2 describes a particular progression with regards to one or more embodiments, other embodiments may follow other progressions in an assembly of the package 90 and/or covered package 95. For example, in one embodiment, the laminate 40 may be added to the package portion 10 after placement of the die 50 of the package and either before or after wire bonding with the wire bond 60. In yet another embodiment, the laminate 40 may be removed before the mold compound 80 has cured or before the mold compound 80 has been disposed around the die 50, wire bonds 60, and die bond 70. Yet other progressions may be utilized in other embodiments.

Although the present invention has been described with several embodiments, a myriad of changes, variations, alterations, transformations, and modifications may be suggested to one skilled in the art, and it is intended that the present invention encompass such changes, variations, alterations, transformation, and modifications as they fall within the scope of the appended claims.

What is claimed is:

1. A method of assembling a package, the method comprising:
coupling a plurality of solder balls to a first surface of a substrate, at least one of the plurality of solder balls in communication with a trace that extends from the first surface of the substrate to a second surface of the substrate;
disposing a removable laminate over the plurality of solder balls;
coupling a die to the second surface of the substrate;
establishing communication between the die and the at least one of the plurality of solder balls through the trace by wire bonding the die to the trace;
disposing a mold compound around the die;
removing the removable laminate to expose the plurality of solder balls; and
wherein coupling the die to the second surface of the substrate, wire bonding the die to the trace, and disposing the mold compound around the die are carried out after disposing the removable laminate over the plurality of solder balls and before removing the removable laminate.

2. The method of claim 1, wherein the plurality of solder balls has a center-to-center spacing less than or equal to 50 mils.

3. The method of claim 1, wherein the plurality of solder balls has a center-to-center spacing less than or equal to 25 mils.

4. The method of claim 1, wherein the plurality of solder balls has a center-to-center spacing less than or equal to 15 mils.

5. The method of claim 1, further comprising: transporting the package to a desired location prior to removing the removable laminate.

6. The method of claim 1, wherein coupling the plurality of solder balls to the first surface of a substrate is carried out using a screen print and reflow process.

7. A method of assembling a package, the method comprising:
coupling a plurality of solder balls to a first surface of a substrate; and
disposing a removable laminate over the plurality of solder balls.

8. The method of claim 7, further comprising:
coupling a die to a second surface of the substrate; and
establishing communication between the die and at least one of the plurality of solder balls.

9. The method of claim 8, wherein
the at least one of the plurality of solder balls is in communication with a trace that extends from the first surface of the substrate to the second surface of the substrate; and
establishing communication between the die and the at least one of the plurality of solder balls includes wire bonding the die to the trace to establish communication between the die and the at least one of the plurality of solder balls through the trace.

10. The method of claim 8, further comprising:
disposing a mold compound around the die; and
removing the removable laminate to expose the plurality of solder balls, wherein coupling the die to the second surface of the substrate, establishing communication between the die and the at least one of the plurality of solder balls, and disposing the mold compound around the die are carried out before removing the removable laminate.

11. The method of claim 10, wherein coupling the die to the second surface of the substrate, establishing communication between the die and the at least one of the plurality of solder balls, and disposing the mold compound around the die are carried out after disposing the removable laminate over the plurality of solder balls.

12. The method of claim 8, further comprising:
disposing a mold compound around the die; and
removing the removable laminate to expose the plurality of solder balls, wherein coupling the die to the second surface of the substrate, establishing communication between the die and the at least one of the plurality of solder balls, and disposing the mold compound around the die are carried out after disposing the removable laminate over the plurality of solder balls.

13. The method of claim 7, wherein the plurality of solder balls has a center-to-center spacing less than or equal to 25 mils.

14. The method of claim 7, wherein the plurality of solder balls has a center-to-center spacing less than or equal to 15 mils.

15. A covered package, comprising:
a substrate having a first surface and a second surface;
a plurality of solder balls coupled to the first surface of the substrate; and
a removable laminate disposed over the plurality of balls.

16. The package of claim 15, further comprising:
a die coupled to the second surface of the substrate, wherein the die is in communication with at least one of the plurality of solder balls.

17. The package of claim 16, further comprising:
a trace that extends from the first surface of the substrate to the second surface of the substrate, wherein the at least one of plurality of solder balls is in communication with the trace; and
a wire bond coupled to the die and to the trace, the wire bond establishing communication between the die and the at least one of the plurality of solder balls through the trace.

18. The package of claim 16, further comprising:
a mold compound disposed around the die.

19. The method of claim 15, wherein the plurality of solder balls has a center-to-center spacing less than or equal to 25 mils.

20. The method of claim 15, wherein the plurality of solder balls has a center-to-center spacing less than or equal to 15 mils.
